(19) United States
(12) Patent Application Publication
(10) Pub. No.: US 2014/0284077 A1
(43) Pub. Date: Sep. 25, 2014

(54) BUS BAR, ELECTRONIC COMPONENT, AND MANUFACTURING METHOD OF ELECTRONIC COMPONENT

(71) Applicant: Kabushiki Kaisha Toshiba, Minato-ku (JP)

(72) Inventors: Tetsuo SAKAI, Tokyo (JP); Naotada Okada, Yokohama-shi (JP)

(73) Assignee: Kabushiki Kaisha Toshiba, Minato-ku (JP)

(21) Appl. No.: 14/039,004

(22) Filed: Sep. 27, 2013

(30) Foreign Application Priority Data
Mar. 22, 2013 (JP) 2013-059277

(51) Int. Cl. H01B 1/02; H01B 13/00

(52) U.S. Cl. CPC H01B 1/02; H01B 13/0036
USPC 174/126.2; 29/825

(57) ABSTRACT

According to one embodiment, a manufacturing method of an electronic component comprises laminating aluminum plates via a nickel member in at least a part thereof; forming a bus bar having welded portions and non-welded portions by welding part of the laminated aluminum plates and the nickel member at positions; and welding an electrode terminal of an electronic component to the aluminum plates and the nickel member.

### CROSS-REFERENCE TO RELATED APPLICATIONS

This application is based upon and claims the benefit of priority from Japanese Patent Application No. 2013-059277, filed Mar. 22, 2013, the entire contents of which are incorporated herein by reference.

### FIELD

Embodiments described herein relate generally to a bus bar, an electronic component using the bus bar, and a manufacturing method of the electronic component.

### BACKGROUND

In an electronic component such as a battery module or a power semiconductor module, as a member that connects an electrode terminal, a bus bar made of a metal material is used. As a technology that copes with realization of a large current that flows through an electrode terminal in an electronic component, e.g., capacity enlargement of a battery module, a technology that increases a board thickness of a bus bar is known.

Further, stress is applied to a bus bar and a position between the bus bar and an electrode terminal due to use of an electronic component in an environment where vibration, thermal expansion of an electronic component itself, or other conditions are present. When a board thickness of the bus bar increases, the rigidity of the bus bar is improved, and hence the stress is concentrated on the position between the bus bar and the electrode terminal.

### BRIEF DESCRIPTION OF THE DRAWINGS

FIG. 1 an explanatory view schematically showing a configuration of an electronic component according to a first embodiment;

FIG. 2 is a perspective view showing a primary configuration of the electronic component;

FIG. 3 is an enlarged cross-sectional view showing a configuration of a bus bar used in the electronic component;

FIG. 4 is an explanatory view showing part of a manufacturing process of the electronic component;

FIG. 5 is an explanatory view of part of the manufacturing process of the electronic component;

FIG. 6 is an explanatory view showing part of the manufacturing process of the electronic component;

FIG. 7 is an explanatory view showing part of the manufacturing process of the electronic component; and

FIG. 8 is a perspective view schematically showing a primary configuration of an electronic component according to a second embodiment.

### DETAILED DESCRIPTION

In general, according to one embodiment, a manufacturing method of an electronic component comprises laminating aluminum plates via a nickel member in at least part thereof; forming a bus bar having welded portions and non-welded portions by welding part of the laminated aluminum plates and the nickel member at positions; and welding an electrode terminal of an electronic component to the aluminum plates and the nickel member.

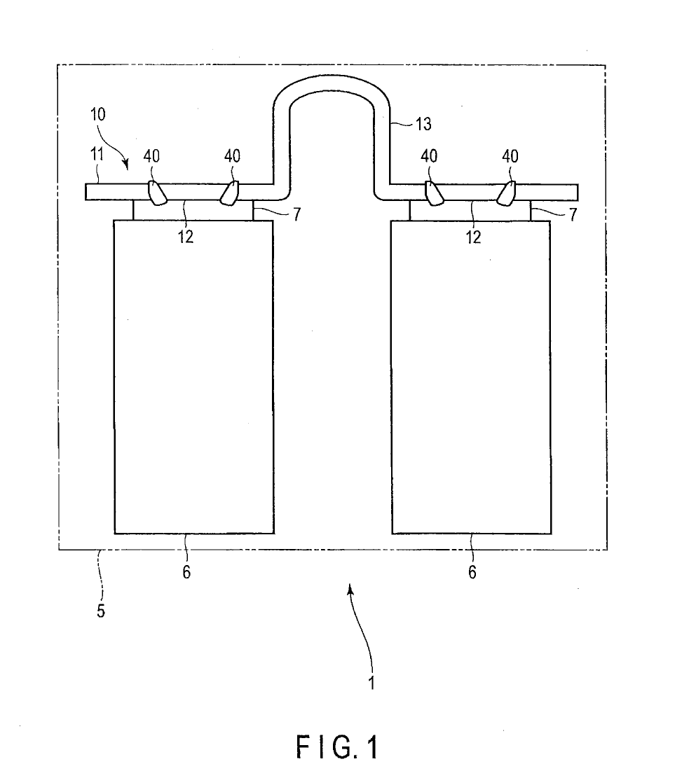

An electronic component 1 using a bus bar 10 and a manufacturing method of the electronic component 1 according to this embodiment will now be described hereinafter with reference to FIG. 1 to FIG. 7.

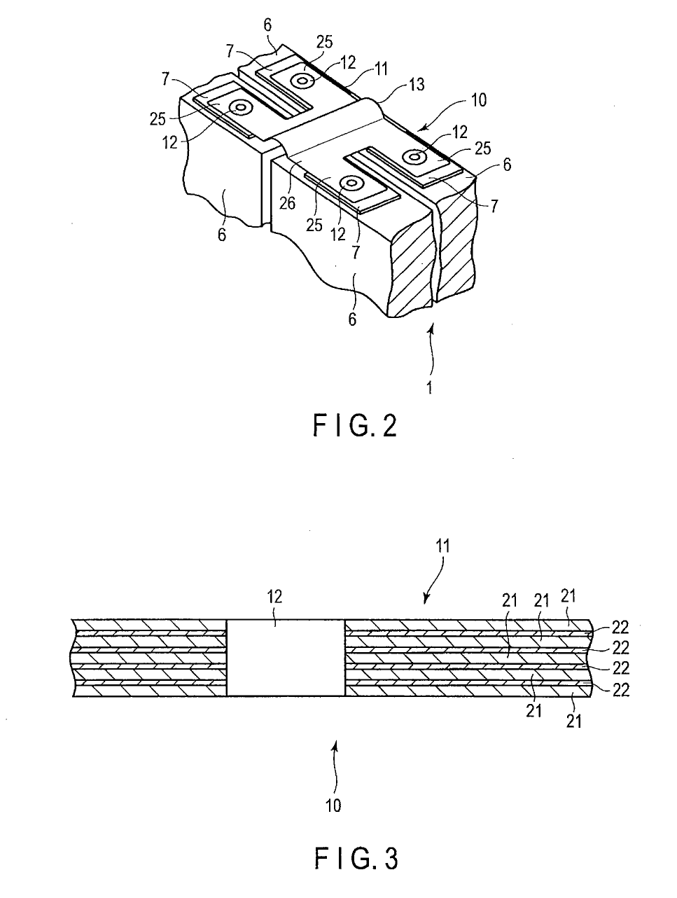

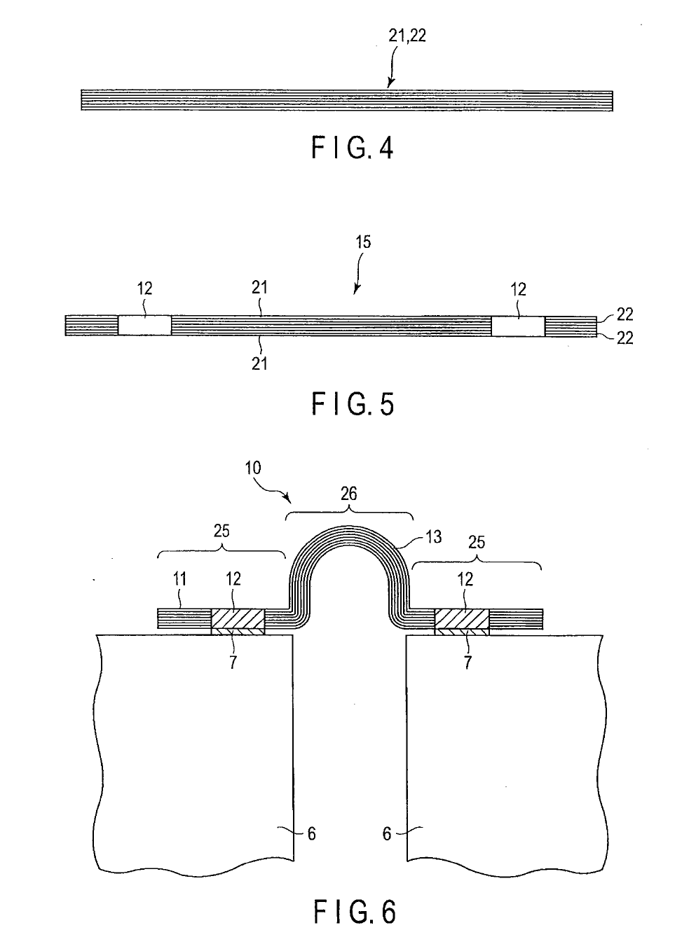

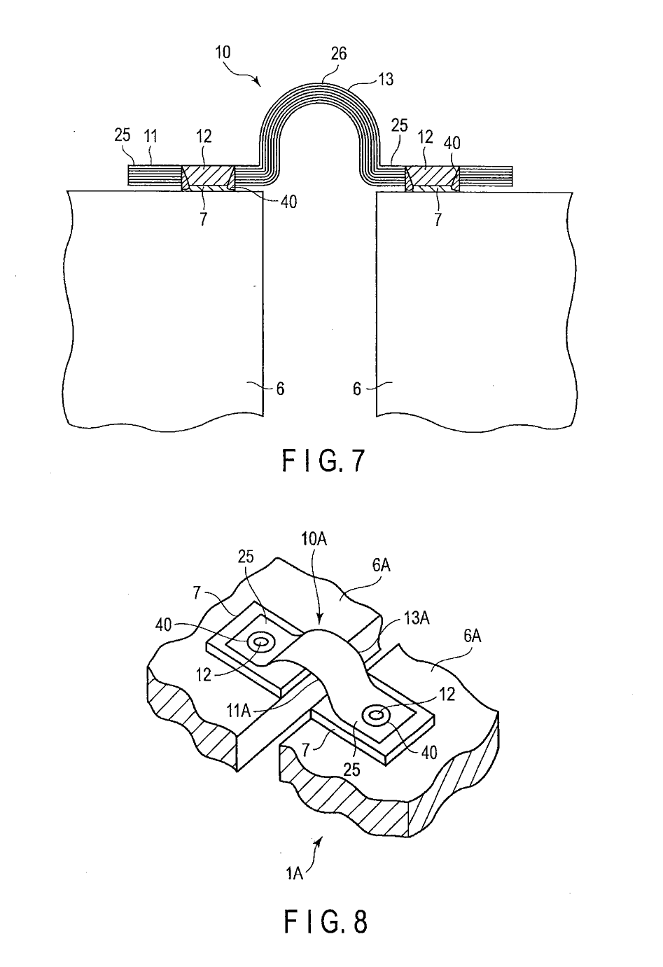

FIG. 1 is an explanatory view schematically showing a configuration of a battery module 1 which is an electronic component 1 according to a first embodiment; FIG. 2 is a perspective view showing a configuration of cells 6 and a bus bar 10 as a primary configuration of the battery module; FIG. 3 is an enlarged cross-sectional view showing a configuration of the bus bar 10; FIG. 4 is an explanatory view showing part of a manufacturing process of the bus bar 10 which is part of a manufacturing process of the battery module 1; FIG. 5 is an explanatory view showing part of the manufacturing process of the bus bar 10; FIG. 6 is an explanatory view showing part of the manufacturing process of the battery module 1; and FIG. 7 is an explanatory view showing part of the manufacturing process of the battery module 1.

As shown in FIG. 1, the electronic component 1 is constituted by connecting electrode terminals 7 of component main bodies 6 through the bus bar 10. In this embodiment, the electronic component 1 is a battery module 1 comprising cells 6 as the component main bodies 6. The electronic component 1 will be described as the battery module 1 hereinafter.

The battery module 1 comprises a container 5, the cells 6 accommodated in the container 5, and the bus bar 10 connecting the cells 6 to each other. For example, as shown in FIG. 2, the battery module 1 is formed by connecting the four cells 6 through one bus bar 10.

Each cell 6 is formed by accommodating an electrode body and an electrolyte therein. The cell 6 comprises the electrode terminal 7 provided outside thereof. Each cell 6 is integrally connected with the bus bar 10 through joining portions 40 when the electrode terminal 7 is welded to the bus bar 10, and is also connected to the electrode terminals 7 of the other cells 6 through the bus bar 10.

The electrode terminal 7 is made of an aluminum material containing Mg. The electrode terminal 7 is made of an aluminum material configured so that the concentration of Mg is 1.25 volume % to 2.51 volume %, e.g., 5052 aluminum. Each electrode terminal 7 is welded to the bus bar 10 through the joining portions 40.

As shown in FIG. 1, FIG. 2, FIG. 6, and FIG. 7, the bus bar 10 comprises a stack member 11, welded portions 12 formed in part of the stack member 11, and a bent portion 13 formed at part of the stack member 11.

The stack member 11 is a plate-like conductive member obtained by integrally forming sheet-like members at positions through the welded portions 12. Specifically, as shown in FIG. 3, the stack member 11 is formed of laminated sheet-like aluminum members 21. Further, the stack member 11 also comprises sheet-like nickel members 22 interposed between the aluminum members 21. As shown in FIG. 5 to FIG. 7, the stack member 11 is constituted by forming the welded portions 12, which fix the laminated aluminum members 21, in part of the laminated aluminum members 21 and nickel members 22.

As shown in FIG. 3, the stack member 11 is formed of, e.g., five aluminum members 21 and four nickel members 22 interposed between the respective aluminum members 21.

As shown in FIG. 2, the stack member 11 comprises a pair of end portions 25 formed at each of both ends thereof and a central portion 25 that continuously connects the four end portions 25. As shown in FIG. 2, the stack member 11 is formed into an H-like shape in plane view. The bent portion 13 is formed at the central portion 26.

The aluminum member 21 is formed into the same shape as the planar shape of the stack member 11. The aluminum member 21 is made of, e.g., pure aluminum. The aluminum member 21 is formed with a thickness of, e.g., 100 μm.

The nickel member 22 is formed into, e.g., the same shape as the aluminum member 21 or at least the same shape as the joining portion 40 that is joined to the welded portion 12 of the stack member 11 and the electrode terminal 7. Each nickel member 22 is formed with a volume that turns to a predetermined melt volume when it melts with each aluminum member 21 in a case where the welded portion 12 is formed or a case where the electrode terminal 7 and the bus bar 10 are welded.

For example, the nickel member 22 is formed with a melt volume that allows the Ni concentration to become 1.2 volume % or more and 49.1 volume % or less when it is welded with each aluminum member 21 and each electrode terminal 7. For example, the nickel member 22 is formed with a thickness of 10 μm.

It is to be noted that 1.2 volume %, which is a lower limit value of Ni concentration, is a concentration that enables the welded portion 12 to be molten with the electrode terminal 7, for example, when the Mg concentration in a material of the electrode terminal 7 is 1.25 volume %. It is to be noted that, for example, in a case of welding the bus bar 10 to the electrode terminal having a different composition, the Ni concentration of each welded portion 12 can be appropriately set.

Further, 49.1%, which is an upper limit value of the Ni concentration, is a value which is set as an upper limit value required in terms of a configuration of the bus bar 10. That is, even if the Ni concentration is equal to or above the upper limit value, each welded portion 12 can be welded to the electrode terminal 7. However, since the bus bar 10 has a configuration that the nickel members 22 are interposed between the aluminum members 21, considering a thickness of each nickel member 22 that can realize the bus bar 10 that is constituted by laminating the aluminum members 21, approximately 49.1 volume % is preferable as the Ni concentration, and hence this value is set as the upper limit value. Therefore, for example, if the nickel members 22 can be supplied to the aluminum members 21 by any means other than lamination, the upper limit value of the Ni concentration is not restricted thereto.

Each welded portion 12 is formed by spot-joining the aluminum members 21 and the nickel members 22 by, e.g., laser welding, ultrasonic welding, or resistance welding.

The welded portion 12 is formed with a melt volume that allows Al in each aluminum member 21 and Ni in each nickel member 22 composing the welded portion 12 to have predetermined volumes, e.g., Ni concentration that is 1.2 volume % or more and 49.1 volume % or less.

The bent portion 13 is provided at, e.g., the central portion 26 of the stack member 11. In other words, the bent portion 13 is provided between both ends of the stack member 11, i.e., one pair of end portions 25 and the other pair of end portions 25 provided to the stack member 11, respectively.

The bent portion 13 is formed so that it can alleviate stress of the bus bar 10 when the stress is applied to the bus bar 10 due to, e.g., vibration or movement of each cell 6 connected to each end portion 25 of the bus bar 10. The bent portion 13 is extended between a pair of cells 6 connected to the end portions 25 of the stack member 11 in a direction orthogonal to a direction along which the pair of cells 6 are in proximity to each other. The bent portion 13 has, e.g., a U-like cross-sectional shape.

Each joining portion 40 is formed with a melt volume that allows Ni in each nickel member 22 composing the joining portion 40 to have a predetermined melt volume, e.g., 1.2 volume % or more and 49.1 volume % as the Ni concentration.

A manufacturing method of the thus configured battery module 1 will now be described.

First, as shown in FIG. 4, the aluminum members 21 are laminated, and the nickel members 22 are interposed at positions where at least each molded portion 12 and each joining portion 40 are formed. For example, as shown in FIG. 3, the aluminum members 21 and the nickel members 22 are alternately laminated. Then, as shown in FIG. 5, the aluminum members 21 and the nickel members 22 are spot-jointed at positions by laser welding, thereby forming each welded portion 12. As a result, the stack member 11 having the aluminum members 21 is integrally laminated through the nickel members 22.

Then, the bent portion 13 is formed at part of the stack member 11, e.g., the central portion 26 by press working or the like as shown in FIG. 6. Based on such a process, the bus bar 10 having the welded portion 12 and the bent portion 13 provided in the stack member 11 is formed.

Then, as shown in FIG. 6, the bus bar 10 is arranged on the electrode terminals 7 of the cells 6. Subsequently, as shown in FIG. 7, the electrode terminals 7 of cells 6 are joined to the end portions 25 of the bus bar 10 by laser welding. It is to be noted that each joining portion 40 of the electrode terminal 7 and the end portion 25 is formed into, e.g., an annular shape. Further, in each end portion 25 of the bus bar 10, for example, the welded portion 12 is joined to the electrode terminal 7. Based on these processes, the bus bar 10 is manufactured, and the bus bar 10 is connected to the cells 6, whereby the battery module 1 is manufactured.

According to the thus configured battery module 1, the bus bar 10 is integrally constituted by laminating the plate-like aluminum members 21 and forming the welded portions 12 in a part of them. Therefore, the bus bar 10 can assure a flow path area of a current that passes through the bus bar 10, and can thus be used even in a large-capacity battery module 1.

Further, since part of the aluminum members 21 is integrally welded and the other part of the same is constituted by lamination of the aluminum members 21, improvement of rigidity of the bus bar 10 can be avoided as much as possible. That is, the bus bar 10 can have low rigidity and, even if vibration applied to the battery module 1 is conducted to the cells 6, the vibration can be absorbed by deformation of each aluminum member 21. That is, when the stress applied to the bus bar 10 from the outside is absorbed by the aluminum members 21, the stress applied can be alleviated.

Furthermore, when the bus bar 10 is configured with the bent portion 13 provided thereto, the vibration conducted to the cells 6 can be further absorbed by the bent portion 13. As a result, the stress produced by the vibration can be prevented from being concentrated on each joining portion 40 of the bus bar 10 and the electrode terminal 7 as much as possible, and fracture of the joining portion 40 can be avoided.

Moreover, in the bus bar 10, cracks or air bubbles can be prevented from being produced between the aluminum members 21 by laminating the aluminum members 21 and providing the nickel members 22 to the welded portions 12 where the laminated aluminum members 21 are welded. When pure aluminum is used for the aluminum members 21 in particular, an oxide film formed on a surface of each aluminum member 21 can be a cause that produces air bubbles, but production of the air bubbles can be avoided. Likewise, in a case of welding the bus bar 10 to each electrode terminal 7, when the nickel members 22 are provided in the bus bar 10, cracks can be prevented from being generated in each joining portion 40 at the time of welding with each electrode terminal 7 made of an aluminum material containing Mg.

When the nickel members 22 can avoid production of air bubbles, cracks, and the like in each welded portion 12 formed by welding and each joining portion 40, the strength of each welded portion 12 and each joining portion 40 of the bus bar 10 can be improved.

As described above, in the battery module 1, the stress can be alleviated, the bus bar 10 that can assure a flow path area of a current can be provided, and the strength of the welded portions 12 and the joining portions 4 for the bus bar 10 and the electrode terminals 7 can be improved. As a result, the reliability of the battery module 1 can be improved.

As described above, according to the battery module 1 which is an electronic component of this embodiment, the flow path area of a current in the bus bar 10 can be assured, and the stress can be alleviated.

A configuration of an electronic component 1A according to a second embodiment used in a power semiconductor module 1A will now be described hereinafter with reference to FIG. 8.

FIG. 8 is a perspective view schematically showing a configuration of an electronic component 1A according to the second embodiment. It is to be noted that like reference numerals denote structures which are the same as those in the electronic component 1 according to the first embodiment in the configuration of the electronic component 1A according to the second embodiment, and a detailed description thereof will be omitted.

The electronic component 1A is a power semiconductor module 1A. The power semiconductor module 1A comprises semiconductor packages 6A as component main bodies 6A and a bus bar 10A that connects the semiconductor packages 6A.

The bus bar 10A comprises a stack member 11A, welded portions 12 formed in part of the stack member 11A, and a bent portion 13A formed in part of the stack member 1A.

The stack member 11A is a plate-like conductive member having sheet-like members integrally formed at positions by the welded portions 12. Specifically, the stack member 11A is formed of laminated sheet-like aluminum members 21. Further, the stack member 11A comprises sheet-like nickel members 22 interposed between the aluminum members 21 and welded portions 12 that are formed in part of the laminated aluminum members 21 and nickel members 22 and fix the laminated aluminum members 21 as shown in FIG. 5 to FIG. 7.

As shown in FIG. 8, the stack member 11 is formed into, e.g., a strip-like shape, has the welded portions 12 formed at both ends thereof, and comprises the bent portion 13A between the welded portions 12.

The bent portion 13A is provided on, e.g., a central side of the stack member 11 and formed into an arc shape that is extended in a direction orthogonal to a longitudinal direction of the stack member 11. Furthermore, the bent portion 13A is formed into a shape that can alleviate the stress applied to the bus bar 10A at the time of movement of the electrode terminals 7 or deformation of the semiconductor packages 6A. For example, the bent portion 13A is joined between the electrode terminals 7 arranged in such a manner a length between them can be shorter than a length between regions where joining portions 40 welded to the electrode terminals 7 in the bus bar 10, and it is formed when the stack member 11 is bent due to a difference between these lengths.

According to the thus configured power semiconductor module 1A, like the battery module 1, the bus bar 10A can assure a flow path area of a current and, even if stress is applied to the bus bar 10A due to vibration, thermal expansion, or the like, the stress can be alleviated.

It is to be noted that the electronic components 1 and 1A and the bus bars 10 and 10A according to this embodiment are not restricted to the above configurations. For instance, the description has been given as to the configuration of the bus bar 10 or 10A comprising the bent portion 13 formed by press working or the bent portion 13 formed based on a difference between a length between the regions where the joining portions 40 are formed and a length between the electrode terminals 7 in the bus bar 10 in each of the foregoing examples, but the bus bar may have, e.g., a configuration having no bent portion. For example, although the bus bar has the configuration where the aluminum members 21 are laminated, when stress is applied to a component main body to which the bus bar is joined and the component main body moves in, e.g., a direction to get closer to each other, the stress can be alleviated by formation of the bent portion due to deformation of the bus bar.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A manufacturing method of an electronic component, comprising:
laminating aluminum plates via a nickel member in at least a part thereof;
forming a bus bar having welded portions and non-welded portions by welding part of the laminated aluminum plates and the nickel member at positions; and
welding an electrode terminal of an electronic component to the aluminum plates and the nickel member.

2. The method according to claim 1, further comprising bending part of the bus bar after forming the bus bar.

3. The method according to claim 1,
wherein the electronic component is a battery module, and the electrode terminal is provided to a cell of the battery module.

4. A bus bar comprising:
aluminum plates;
a nickel member interposed in at last a part between the aluminum plates; and
welded portions formed by welding part of the laminated aluminum plates and the nickel member.

5. The bus bar according to claim 4, further comprising a bent portion formed between the welded portions.

6. An electronic component comprising:
component main bodies each comprising an electrode terminal; and
a bus bar which comprises: aluminum plates; a nickel member interposed in at least a part between the aluminum plates; and welded portions formed by welding part of the laminated aluminum plates and the nickel member, and is welded to the electrode terminals of the electronic components.

7. The electronic component according to claim 6,
wherein the bus bar has a bent portion formed at a position between the electrode terminals to which the bus bar is welded.

8. The electronic component according to claim 7,
wherein the component main body is a cell, and the electronic component is a battery module.
